(19) United States
(12) Patent Application Publication
(10) Pub. No.: US 2026/0312545 A1
(43) Pub. Date: Oct. 8, 2026

(54) LOAD IMPEDANCE CIRCUIT FOR AMPLIFIER

(71) Applicant: STMicroelectronics International N.V., Geneva (CH)

(72) Inventor: Valérie DANELON, Crolles (FR)

(21) Appl. No.: 19/574,169

(22) Filed: Mar. 20, 2026

(30) Foreign Application Priority Data
Apr. 3, 2025 (FR) 2503478

(51) Int. Cl. H03F 1/56; H03F 3/21

(52) U.S. Cl. CPC H03F 1/565; H03F 3/21

(57) ABSTRACT

The present description concerns an impedance circuit comprising: a central axis; a stage comprising: a pair of components, connected to a first node, comprising a capacitor and a resistor connected in series, on one side of the central axis; another pair, connected to a second node, comprising a capacitor and a resistor connected in series, on the other side, the pairs being connected via a first central node on the central axis; a first inductor connected to the first node and coupled to a third node and a second inductor connected to the second node and coupled to a fourth node; a third inductor between the first node and a voltage rail and a fourth inductor between the second node and the voltage rail.

### CROSS-REFERENCE TO RELATED APPLICATIONS

This application claims the priority benefit of French patent application number FR2503478, filed on Apr. 3, 2025, entitled “Circuit électronique d’impédance de charge pour un amplificateur”, which is hereby incorporated by reference in its entirety.

### FIELD OF INVENTION

The present disclosure generally concerns electronic amplifiers and in particular electronic load impedance circuits for an amplifier.

### BACKGROUND

An amplifier corresponds to an electronic circuit configured to generate an output signal having an amplitude greater than the input signal. It is known to design amplifiers for a fixed frequency of the input signal or for a fixed frequency range of the input signal. The amplifier components are then defined for this fixed frequency or frequency range.

Broadband amplifiers are configured to amplify an input signal over a relatively wide frequency range for the input signal.

Electronic load impedance circuits for amplifiers are generally formed of one or more elements such as a resistor or a cell comprising one or more inductors or capacitors that can be connected in series and/or in parallel. However, these electronic circuits implementing the load impedance require, for example, components with high values and/or bulky for a broadband amplifier, and often only allow a narrowband operation.

There exists a need for electronic load impedance circuits for a broadband amplifier. There further exists a need for an amplifier with an output impedance which is relative constant or increasing with frequency over a relatively wide frequency range. There also exists a need for an electronic load impedance circuit for an amplifier having a small surface area and an easier common mode management.

### SUMMARY

An embodiment provides an electronic load impedance circuit for an amplifier, comprising: 1) a central axis; 2) a first stage comprising: a first pair of components comprising a capacitor and a resistor connected together in series, the first pair of components being connected to a first node; a second pair of components comprising a capacitor and a resistor connected together in series, the second pair of components being connected to a second node, the first pair of components being positioned on a first side of the central axis and the second pair of components being positioned on a second side, opposite to the first side, of the central axis, and the first and the second pair of components being connected together via a first central connection node belonging to the central axis; a first inductor connected to the first node and a second inductor connected to the second node, the first inductor being further coupled to a third node and the second inductor being further coupled to a fourth node; and 3) a third inductor between the first node and a rail of application of a first reference voltage, and a fourth inductor between the second node and the rail of application of the first reference voltage.

According to an embodiment, the first central connection node is connected to the rail of application of the first reference voltage.

According to an embodiment, the first central connection node is connected to a rail of application of a second reference voltage different from the first reference voltage.

According to an embodiment, the first central connection node is floating.

According to an embodiment, the third node and fourth node form a differential output.

According to an embodiment, an inductive loop is configured to implement at least two inductors from among the first inductor, the second inductor, the third inductor, and the fourth inductor.

According to an embodiment, one or more inductors from among the first inductor, the second inductor, the third inductor, and the fourth inductor are implemented by a figure-of-eight inductor or by an inductor comprising two concentric loops or by an inductor comprising three concentric loops.

According to an embodiment, the circuit further comprises a second stage comprising: a first pair of components comprising a capacitor and a resistor connected together in series, the first pair of components being connected to the third node; a second pair of components comprising a capacitor and a resistor connected together in series, the second pair of components being connected to the fourth node, the first pair of components being positioned on the first side of the central axis and the second pair of components being positioned on the second side, opposite to the first side, of the central axis, and the first and the second pair of components being connected to each other via a second central connection node belonging to the central axis; and a fifth inductor connected to the third node and a sixth inductor connected to the fourth node, the fifth inductor being further coupled to a fifth node and the sixth inductor being further coupled to a sixth node.

According to an embodiment, the second central connection node is connected to the rail of application of the first reference voltage.

According to an embodiment, the second central connection node is connected to the rail of application of the second reference voltage.

According to an embodiment, the second central connection node is floating.

According to an embodiment, the fifth node and the sixth node form a differential output.

According to an embodiment, the first pair of components and the second pair of components of each stage are arranged symmetrically with respect to the central axis.

An embodiment provides an amplifier comprising the impedance circuit detailed hereabove.

According to an embodiment, the amplifier is configured to receive a radio wave, the radio wave having a frequency in the range from 1 GHz to 200 GHz.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows a system comprising an electronic load impedance circuit and an amplifier according to an embodiment of the present disclosure;

FIG. 2A schematically shows an electronic load impedance circuit comprising one stage according to an embodiment of the present disclosure;

FIG. 2B schematically shows an electronic load impedance circuit comprising two stages according to an embodiment of the present disclosure;

FIG. 3A schematically shows an electronic load impedance circuit comprising one stage according to another embodiment of the present disclosure;

FIG. 3B schematically shows an electronic load impedance circuit comprising two stages according to another embodiment of the present disclosure;

FIG. 4A schematically shows an electronic load impedance circuit comprising one stage according to another embodiment of the present disclosure;

FIG. 4B schematically shows an electronic load impedance circuit comprising two stages according to another embodiment of the present disclosure;

FIG. 5 is a graph showing S-parameters (“scattering parameters”) for the adaptation at the input, at the output, and in transmission, of the signal by the circuits of FIGS. 2A and 3A;

FIG. 6A is a top view of the circuit of FIG. 2A, and illustrates an example of routing of the circuit of FIG. 2A according to an embodiment of the present disclosure; and

FIGS. 6B, 6C, 6D, 6E, and 6F are top views of the circuit of FIG. 4A, and illustrate examples of routing of the circuit of FIG. 4A according to an embodiment of the present disclosure.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail. In particular, an amplifier is known to those skilled in the art and the routing between an amplifier and a load impedance circuit is known to those skilled in the art.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10%, preferably of plus or minus 5%.

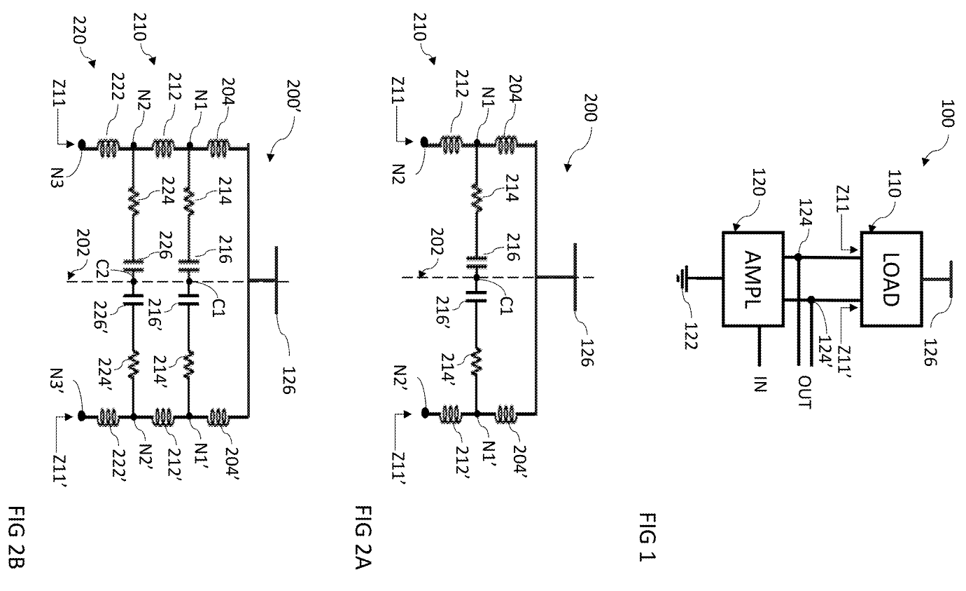

FIG. 1 schematically shows a system 100 comprising an electronic load impedance circuit 110 ("LOAD") and an amplifier 120 ("AMPL") according to an embodiment of the present disclosure.

Amplifier 120 is for example configured to receive an input signal on an input ("IN") of system 100 and to transmit an output signal from an output ("OUT") of system 100. The amplitude of the output signal is, for example, greater than the amplitude of the input signal. The amplitude of the input signal is multiplied, for example, by a gain depending on the circuit defined by amplifier 120.

According to an embodiment, amplifier 120 is a differential amplifier, that is, an amplifier enabling to receive and amplify a differential signal.

Amplifier 120 is for example coupled to a first reference voltage 122, for example a ground rail, and is for example coupled to the output OUT of system 100. In the example of FIG. 1, output OUT is a differential output coupled to one connection node 124 and to another connection node 124'. Amplifier 120 is coupled to connection nodes 124 and 124'.

Amplifier 120 is, for example, a low-noise amplifier, a power amplifier, etc. For example, amplifier 120 comprises two transistors, for example two MOS transistors, connected in cascode.

Amplifier 120 is, for example, a radio frequency amplifier configured to receive radio waves as an input.

According to an embodiment, amplifier 120 is a broadband amplifier, for example configured to amplify an input signal over a frequency range having an amplitude greater than or equal to 10 GHz, and for operating frequencies ranging, for example, from 1 GHz to 200 GHz.

Load impedance circuit 110 is for example coupled to a rail of application of a second reference voltage 126 different from the first reference voltage 122, the second reference voltage 126 being for example higher than the first reference voltage 122. Load impedance circuit 110 is for example coupled to the output OUT of system 100, for example via connection nodes 124 and 124'.

Load impedance circuit 110 is configured, for example, to generate and set an output impedance Z11 on connection node 124 and an output impedance Z11' on connection node 124'. Output impedances Z11 and Z11' are, for example, substantially similar or assumed to be similar. Output impedances Z11 and Z11' correspond, for example, to the output impedances of amplifier 120.

According to an embodiment, output impedances Z11 and Z11' are constant or substantially invariant as a function of the frequency of the input signal, over at least part of the frequency range of the input signal of the amplifier.

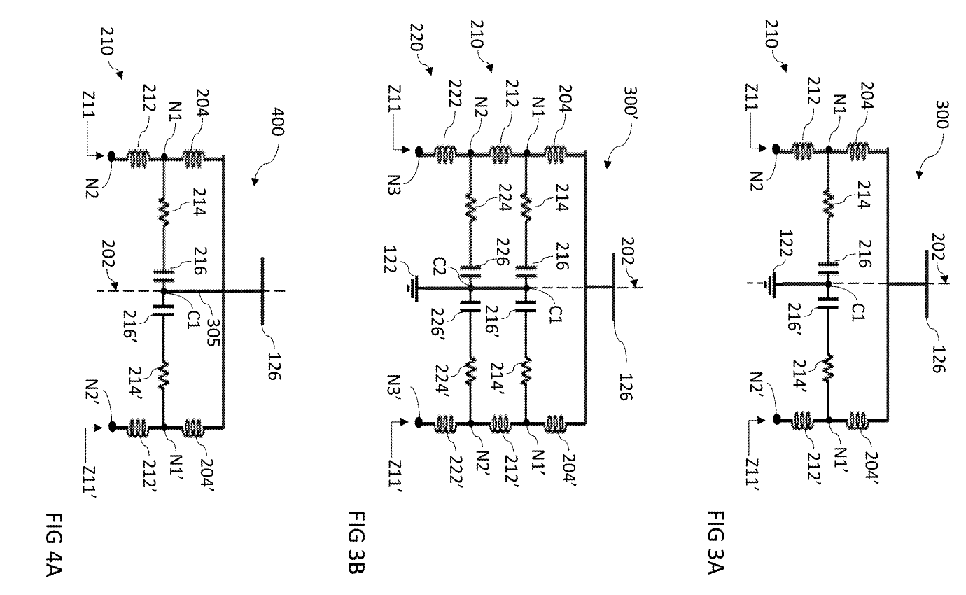

FIG. 2A schematically shows an electronic load impedance circuit 200 comprising one stage according to an embodiment of the present disclosure.

Circuit 200 comprises a central axis 202. Central axis 202 is for example an axis of symmetry of circuit 200, implying that circuit 200 comprises identical sub-circuits on each side of central axis 202, the sub-circuits comprising the same components arranged symmetrically with respect to central axis 202. Further, although FIG. 2A is only a simplified drawing, circuit 200 is part, for example, of an integrated circuit, or of a printed circuit board (PCB), and the symmetry between the sub-circuits of circuit 200 concerns, for example, the physical layout of the components.

Circuit 200 comprises, in a first sub-circuit on a first side of central axis 202, a first inductor 204 coupled, preferably connected, between the rail of application of the second reference voltage 126, described in relation with FIG. 1, and a connection node N1.

Circuit 200 comprises, in a second sub-circuit on a second side of central axis 202, opposite to the first side, a second inductor 204' coupled, preferably connected, between the rail of application of the second reference voltage 126, described in relation with FIG. 1, and a connection node N1'.

According to an embodiment, the first inductor 204 and the second inductor 204' are arranged symmetrically with respect to central axis 202. The first inductor 204 and the second inductor 204' have a similar inductance value, for example in a range from 10 picohenries (pH) to 1,000 pH.

In the example of FIG. 2A, circuit 200 comprises a stage 210. Stage 210 comprises: in the first sub-circuit, an inductor 212 coupled, preferably connected, between connection node N1 and a connection node N2; in the second sub-circuit, an inductor 212' coupled, preferably connected, between connection node N1' and a connection node N2'; in the first sub-circuit, a first pair of components, comprising a resistor 214 and a capacitor 216, connected in series between connection node N1 and a first central connection node C1; and in the second sub-circuit, a second pair of components, comprising a resistor 214' and a capacitor 216', connected in series between connection node N1' and the first central connection node C1.

Connection node N2 corresponds, for example, to the connection node 124 described in relation with FIG. 1, and connection node N2' corresponds, for example, to the connection node 124' described in relation with FIG. 1.

According to an embodiment, the first central connection node C1 belongs to central axis 202.

According to an embodiment, a single capacitor is configured to implement capacitors 216 and 216', so that the capacitance of the single capacitor is equal to the equivalent capacitance of capacitor 216 connected in series with capacitor 216'. The first central connection node C1 is then located in the single capacitor, for example at the center of the single capacitor.

According to an embodiment, the first pair of components and the second pair of components are arranged symmetrically with respect to central axis 202. Resistors 214 and 214' have, for example, a similar resistance value, for example in a range from 10 Ω to 500 Ω. Capacitors 216 and 216' have, for example, a similar capacitance value, for example in a range from 100 femptofarads (fF) to 5,000 fF.

According to an embodiment, inductors 212 and 212' are arranged symmetrically with respect to central axis 202. Inductors 212 and 212' for example have a similar inductance value, for example in a range from 10 pH to 2,000 pH. According to an embodiment, inductor 212 has a lower inductance value than inductor 204 and inductor 212' has a lower inductance value than inductor 204'.

The values of the components of circuit 200 are for example selected so as to generate an output impedance Z11 and a relatively constant output impedance Z11', increasing or decreasing as a function of the frequency of the input signal, over at least part of the frequency range of the input signal of the amplifier. In particular, the values of the components of circuit 200 are for example selected so as to control the resonance phenomenon over the entire frequency range of the amplifier input signal. Each pair of components, comprising a resistor and a capacitor connected in series, is configured, for example, to control the resonance phenomenon of the inductor closest to the rail of application of the second reference voltage 126 among the inductors to which it is directly connected.

For example, at relatively low frequencies, capacitors 216 and 216' have a behavior similar to that of an open switch, and output impedances Z11 and Z11' are approximately equal to the sum of the values of inductors 204 and 212, and 204' and 212' respectively. For input signal frequency values close to the resonance frequency of inductor 204, resistor 214 is for example configured to attenuate or compensate for the resonance phenomenon and the inductance of output impedance Z11 is approximately equal to the value of inductor 212, for example. Similarly, for input signal frequencies close to the resonance frequency of inductor 204', resistor 214' is configured to attenuate or compensate for the resonance phenomenon, and the inductance of output impedance Z11' is for example approximately equal to the value of inductor 212'. Inductor 212, for example, has an inductance value lower than that of inductor 204, whereby inductor 212 starts resonating for a frequency higher than the resonance frequency of inductor 204, and for example for a frequency higher than the frequency of the input signal of the amplifier. Similarly, inductor 212' has, for example, an inductance value lower than that of inductor 204', whereby inductor 212' starts resonating at a frequency higher than the resonance frequency of inductor 204', and for example at a frequency higher than the frequency of the input signal of the amplifier.

According to another embodiment, inductor 212 has an inductance value similar to or greater than that of inductor 204, and inductor 212' has an inductance value similar to or greater than that of inductor 204'.

An advantage of circuit 200 is that its physical implementation can allow an optimization of the occupied surface area. In particular, central connection node C1 is floating. No conduction line is present, for example, to impose a voltage on central connection node C1. Central connection node C1 is thus a virtual ground node. An advantage of having central connection node C1 floating is to have a variable physical implementation requiring no particular connection.

FIG. 2B schematically shows an electronic load impedance circuit 200 comprising two stages according to an embodiment of the present disclosure.

Some elements of FIG. 2B are similar to elements of FIG. 2A, these elements are designated with the same reference and will not be discussed again in detail.

As with the circuit 200 of FIG. 2A, central axis 202 is, for example, an axis of symmetry of circuit 200'.

The difference between circuit 200' and the circuit 200 of FIG. 2A is that circuit 200' comprises a second stage 220.

Stage 220 comprises: in the first sub-circuit, an inductor 222 coupled, preferably connected, between connection node N2, described in relation with FIG. 2A, and a connection node N3; in the second sub-circuit, an inductor 222' coupled, preferably connected, between a connection node N2', described in relation to FIG. 2A, and a connection node N3'; in the first sub-circuit, a first pair of components, comprising a resistor 224 and a capacitor 226, connected in series between connection node N2 and a second central connection node C2; and in the second sub-circuit, a second pair of components, comprising a resistor 224' and a capacitor 226', connected in series between connection node N2' and the second central connection node C2.

Connection node N3 corresponds, for example, to the connection node 124 described in relation with FIG. 1, and connection node N3' corresponds, for example, to the connection node 124' described in relation with FIG. 1.

According to an embodiment, the second central connection node C2 belongs to central axis 202. The first central connection node C1 and the second central connection node C2 are for example aligned along central axis 202.

According to an embodiment, a single capacitor is configured to implement capacitors 226 and 226', so that the capacitance of the single capacitor is equal to the equivalent capacitance of capacitor 226 connected in series with capacitor 226'. The second central connection node C2 is then located in the single capacitor, for example at the center of the single capacitor.

According to an embodiment, the first pair of components and the second pair of components of stage 220 are arranged symmetrically with respect to central axis 202. Resistors 224 and 224' for example have a similar resistance value. Capacitors 226 and 226' for example have a similar capacitance value.

According to an embodiment, inductors 222 and 212' are arranged symmetrically with respect to central axis 202. Inductors 222 and 222' for example have a similar inductance value. According to an embodiment, inductor 222 has a lower inductance value than inductor 212, and inductor 222' has a lower inductance value than inductor 212'.

For example, the values of the components of circuit 200' are selected so as to generate an output impedance Z11 and a relatively constant output impedance Z11', increasing or decreasing as a function of the frequency of the input signal, over at least part of the frequency range of the input signal of the amplifier. In particular, the values of the components of circuit 200' are selected, for example, to control the resonance phenomenon over the entire frequency range of the input signal of the amplifier.

For example, for relatively low frequencies, capacitors 216, 216', 226, and 226' have a behavior similar to that of an open switch. Output impedance Z11 is for example approximately equal to the sum of the values of inductors 204, 212, and 222, and output impedance Z11' is, for example, approximately equal to the sum of the values of inductors 204', 212', and 222'.

For input signal frequency values close to the resonance frequency of inductor 204, resistor 214 is configured, for example, to attenuate or compensate for the resonance phenomenon, and output impedance Z11 is approximately equal to the sum of the values of inductors 212 and 222. Similarly, for frequency values of the input signal close to the resonance frequency of inductor 204', resistor 214' is configured to attenuate or compensate for the resonance phenomenon, and output impedance Z11' is approximately equal to the sum of the values of inductors 212' and 222'.

For input signal frequency values close to the resonance frequency of inductor 212, resistor 224 is configured to attenuate or compensate for the resonance phenomenon, and output impedance Z11 is approximately equal to the value of inductor 222. Similarly, for input signal frequency values close to the resonance frequency of inductor 212', resistor 224' is configured to attenuate or compensate for the resonant phenomenon, and output impedance Z11' is approximately equal to the value of inductor 222'. Inductor 222, for example, has an inductance value lower than that of inductor 212, whereby inductor 222 starts resonating at a frequency higher than the resonance frequency of inductor 212, and for example at a frequency higher than the frequency of the input signal of the amplifier. Similarly, inductor 222' has, for example, an inductance value lower than that of inductor 212', whereby inductor 222' starts resonating at a frequency higher than the resonance frequency of inductor 212', and for example at a frequency higher than the frequency of the input signal of the amplifier.

According to another embodiment, inductor 222 has an inductance value similar to or greater than that of each of inductors 212 and 204, and inductor 222' has an inductance value similar to or greater than that of each of inductors 212' and 204'.

An advantage of the addition of the second stage 220 to circuit 200' is a control of output impedances Z11 and Z11' and a compensation of resonance phenomena over a possibly wider frequency range of the input signal and/or with an additional degree of freedom in the definition of the impedance.

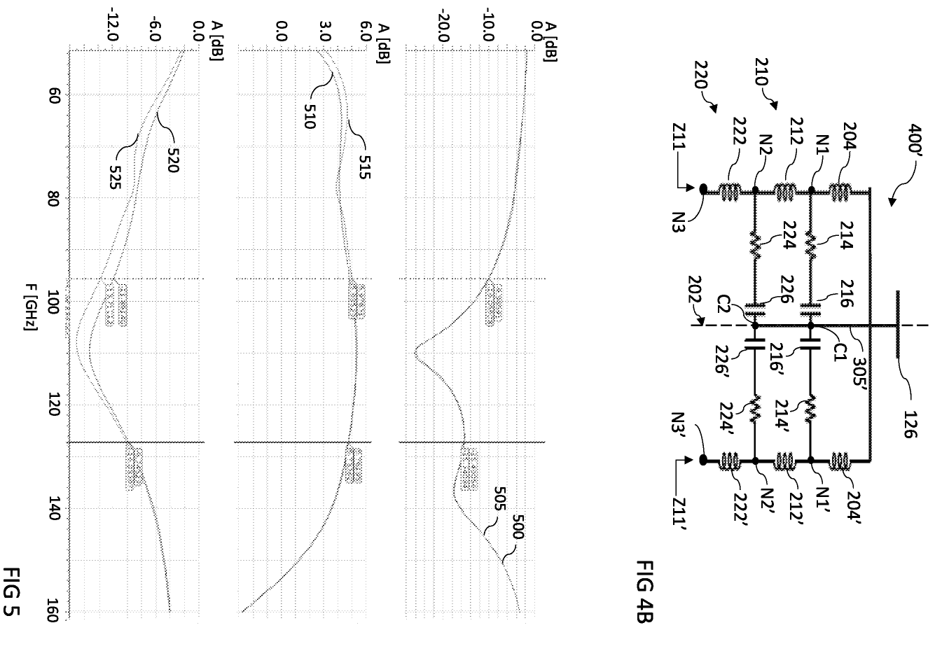

FIG. 3A schematically shows an electronic load impedance circuit 300 comprising a stage according to another embodiment of the present disclosure.

Some elements of FIG. 3A are similar to elements of FIG. 2A, these elements are designated with the same reference and will not be discussed again in detail.

The difference between circuit 300 and the circuit 200 of FIG. 2A is that, in circuit 200, the first central connection node C1 is floating, whereas in circuit 300, the first central connection node C1 is coupled to the first reference voltage 122.

FIG. 3B schematically shows an electronic load impedance circuit 300' comprising two stages according to another embodiment of the present disclosure.

Some elements of FIG. 3B are similar to elements of FIG. 2B, these elements are designated with the same reference and will not be discussed again in detail.

The difference between circuit 300' and the circuit 200' of FIG. 2B is that, in circuit 200', the first central connection node C1 is floating, while in circuit 300', the first central connection node C1 and the second central connection node C2 are coupled to the first reference voltage 122.

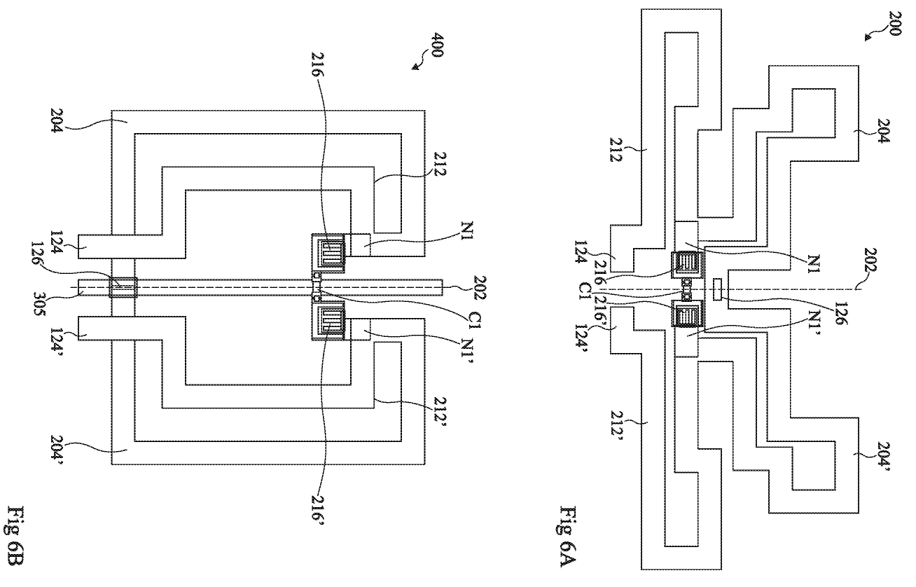

FIG. 4A schematically shows an electronic load impedance circuit 400 comprising a stage according to another embodiment of the present disclosure.

Some elements of FIG. 4A are similar to elements of FIG. 2A, these elements are designated with the same reference and will not be discussed again in detail.

The difference between circuit 400 and the circuit 200 of FIG. 2A is that, in circuit 400, the first central connection node C1 is coupled to the rail of application of the second reference voltage 126, via a conduction line 305.

FIG. 4B schematically shows an electronic load impedance circuit 400' comprising two stages according to another embodiment of the present disclosure.

Some elements of FIG. 4B are similar to elements of FIG. 2B, these elements are designated with the same reference and will not be discussed again in detail.

The difference between circuit 400' and the circuit 200' shown in FIG. 2B is that, in circuit 400', the first central connection node C1 and the second central connection node C2 are coupled to the rail of application of the second reference voltage 126, via a conduction line 305'.

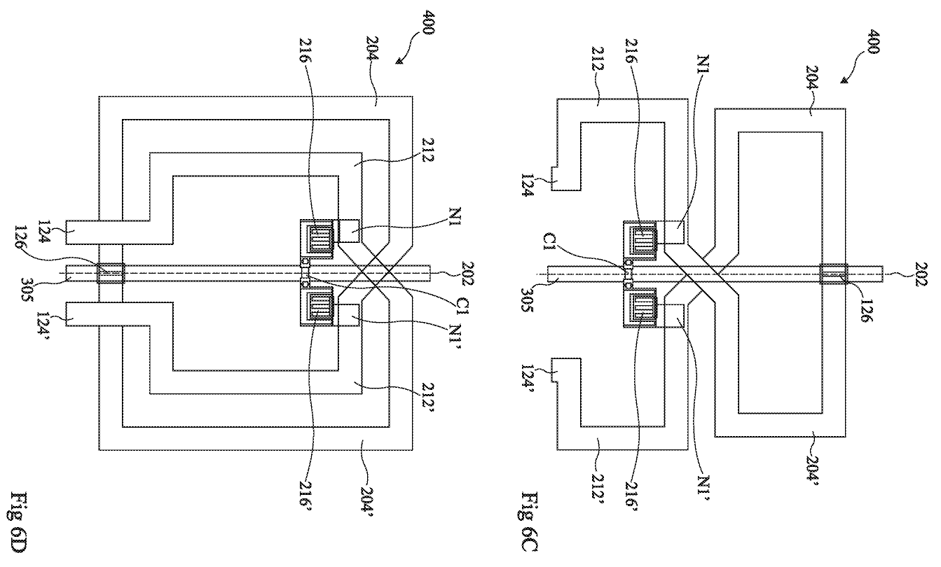

FIG. 5 is a graph showing the amplitude ("A [dB]") of the S-parameters ("scattering parameters") of adaptation, at the input, at the output, and in transmission, of the signal by the circuits of FIGS. 2A and 3A as a function of frequency ("F [GHz]").

The graph comprises six curves 500, 505, 510, 515, 520, and 525. Curves 500 and 505 represent an input reflection coefficient S11 of the system 100 of FIG. 1, comprising circuit 200 and circuit 300 respectively. Curves 510 and 515 represent a power gain S21 of the system 100 of FIG. 1 comprising circuit 200 and circuit 300 respectively. Curves 520 and 525 represent an output reflection coefficient S22 of the system 100 of FIG. 1 respectively comprising circuit 200 and circuit 300.

Curves 500 and 505 are approximately identical between 50 GHz and 160 GHz.

Curves 510 and 515 and curves 520 and 525 have similar amplitude variations between 50 GHz and 160 GHz.

The graph shows that circuits 200 and 300 have a similar behavior between 50 GHz and 160 GHz.

All the circuits described in relation with FIGS. 2A-4B are suitable for a broadband amplifier. In particular, the circuits described in relation with FIGS. 2A-4B have S-parameters having similar variations.

The curves of FIG. 5 show that circuits 200 and 200', in which the central connection node(s) C1, C2 are floating, are adapted to providing an output load impedance for a differential amplifier.

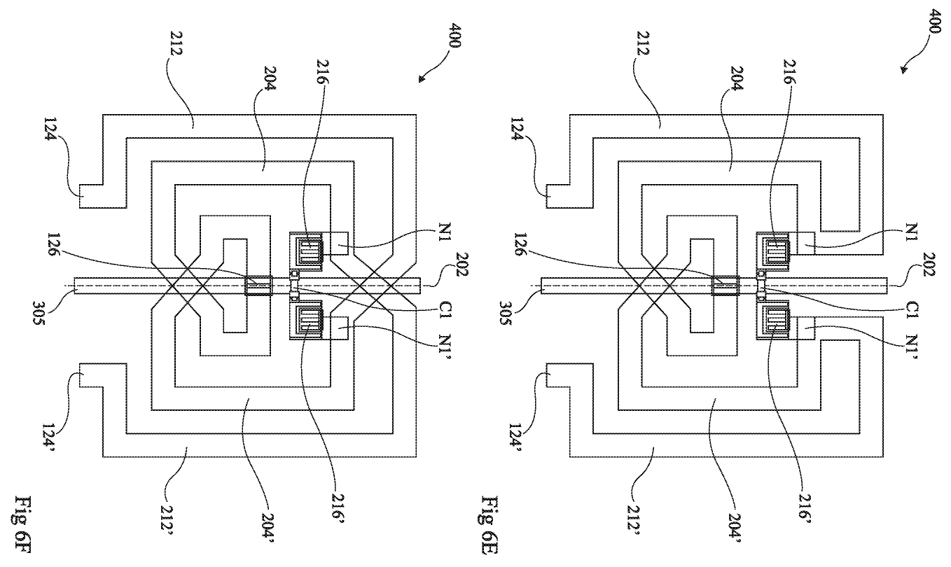

FIG. 6A is a top view of the circuit 200 of FIG. 2A, and illustrates an example of routing of circuit 200 according to an embodiment of the present disclosure.

In the example of FIG. 6A, resistors 214 and 214' correspond to the resistances of the conduction lines and are not identified in the drawing.

In the example of FIG. 6A, each of inductors 204, 212, 204', and 212' corresponds to all or part of an inductor.

In the example of FIG. 6A, central axis 202 is an axis of symmetry of circuit 200. The first sub-circuit and the second sub-circuit are, for example, identical on each side of central axis 202, the sub-circuits comprising the same components placed and arranged in physically symmetrical fashion relative to central axis 202.

FIGS. 6B, 6C, 6D, 6E, and 6F are top views of the circuit 400 of FIG. 4A, and illustrate examples of routing of circuit 400 according to an embodiment of the present disclosure.

Each of inductors 204, 212, 204', and 212' corresponds, for example, to all or part of an inductor. In the example of FIGS. 6B-6F, an inductive loop is configured to implement at least two inductors from among inductors 204, 212, 204', and 212'. The central connection node C1 is coupled to the rail of application of the second reference voltage 126, and the routing is symmetrical with respect to axis 202.

In the example shown in FIGS. 6B-6F, central axis 202 is an axis of symmetry of circuit 400. The first sub-circuit and the second sub-circuit are, for example, identical on each side of central axis 202, the sub-circuits comprising the same components placed and arranged in physically symmetrical fashion relative to central axis 202.

Each of FIGS. 6B-6F illustrates an example of routing of circuit 400. In the example of FIG. 6B, circuit 400 comprises two inductive loops, arranged symmetrically with respect to central axis 202, one configured to implement inductors 204 and 212 and the other configured to implement inductors 204' and 212'. In the example of FIG. 6C, circuit 400 comprises two inductive loops forming a figure-of-eight inductor, each of inductors 204, 212, 204', and 212' being formed by a half-loop. In the example of FIG. 6D, circuit 400 comprises two concentric inductive loops, each of inductors 204, 212, 204', and 212' being formed by a half-loop. In the example of FIG. 6E, circuit 400 comprises three inductive loops. Each of inductors 212 and 212' is formed by a half-loop, and each of inductors 204 and 204' is formed by two half-loops. In the example of FIG. 6F, circuit 400 comprises three concentric inductive loops. Each of inductors 212 and 212' is formed by one half-loop, and each of inductors 204 and 204' is formed by two half-loops. The selection of the routing is for example performed as a function of the available surface area, of the size of each of the circuit components, and of a possible coupling between inductors and capacitors.

Each of the circuits described in relation with FIGS. 2A-4B has a relatively low bulk. In particular, the circuit 200 in which the first central connection node C1 is floating and the circuit 200' in which the first central connection node C1 and the second central connection node C2 are floating have a low bulk.

Each of the circuits described in relation with FIGS. 2A-4B, for example, advantageously has an inductive output impedance Z11, Z11', that is, having a positive imaginary part, for example over the entire frequency range of use of the amplifier, for example over a frequency range having an amplitude greater than or equal to 10 GHz, for example greater than or equal to 100 GHz.

Another advantage of each of the circuits described in relation with FIGS. 2A-4B is that a single circuit is used to control the output impedance of a differential amplifier.

An embodiment provides an electronic load impedance circuit for an amplifier, comprising: 1) a central axis; 2) a first stage comprising: a first resistor connected to a first node; a second resistor connected to a second node, the first resistor being positioned on a first side of the central axis and the second resistor being positioned on a second side, opposite to the first side, of the central axis, and the first and second resistors being connected together via a capacitor located on the central axis; a first inductor connected to the first node and a second inductor connected to the second node, the first inductor being further coupled to a third node and the second inductor being further coupled to a fourth node; and 3) a third inductor connected between the first node and a rail of application of a first reference voltage, and a fourth inductor connected between the second node and the rail of application of the first reference voltage.

An embodiment provides an electronic load impedance circuit for an amplifier, comprising: 1) a central axis; 2) a first stage comprising: a first capacitor connected to a first node; a second capacitor connected to a second node, the first capacitor being positioned on a first side of the central axis and the second capacitor being positioned on a second side, opposite to the first side, of the central axis, and the first and second capacitors being connected together via a resistor located on the central axis; a first inductor connected to the first node and a second inductor connected to the second node, the first inductor being further coupled to a third node and the second inductor being further coupled to a fourth node; and 3) a third inductor connected between the first node and a rail of application of a first reference voltage and a fourth inductor connected between the second node and the rail of application of the first reference voltage.

Various embodiments and variants have been described. Those skilled in the art will understand that certain features of these various embodiments and variants may be combined, and other variants will occur to those skilled in the art. In particular, although the circuits of FIGS. 2A-4B each have one or two stages, a number of stages greater than two is possible.

Finally, the practical implementation of the described embodiments and variants is within the abilities of those skilled in the art based on the functional indications given hereabove.

1. An electronic load impedance circuit for an amplifier, comprising:
1) a central axis;
2) a first stage comprising:
a first pair of components comprising a capacitor and a resistor connected to each other in series, the first pair of components being connected to a first node;
a second pair of components comprising a capacitor and a resistor connected together in series, the second pair of components being connected to a second node, the first pair of components being positioned on a first side of the central axis and the second pair of components being positioned on a second side, opposite to the first side, of the central axis, and the first and the second pair of components being connected to each other via a first central connection node belonging to the central axis; and
a first inductor connected to the first node and a second inductor connected to the second node, the first inductor being further coupled to a third node and the second inductor being further coupled to a fourth node; and
3) a third inductor between the first node and a rail of application of a first reference voltage , and a fourth inductor between the second node and the rail of application of the first reference voltage.

2. The circuit according to claim 1, wherein the first central connection node is connected to the rail of application of the first reference voltage.

3. The circuit according to claim 1, wherein the first central connection node is connected to a rail of application of a second reference voltage different from the first reference voltage.

4. The circuit according to claim 1, wherein the first central connection node is floating.

5. The circuit according to claim 1, wherein the third node and the fourth node form a differential output.

6. The circuit according to claim 1, wherein an inductive loop is configured to implement at least two inductors from among the first inductor, the second inductor, the third inductor, and the fourth inductor.

7. The circuit according to claim 1, wherein one or more inductors from among the first inductor, the second inductor, the third inductor, and the fourth inductor are implemented by a figure-of-eight inductor or by an inductor comprising two concentric loops or by an inductor comprising three concentric loops.

8. The circuit according to claim 1, further comprising a second stage comprising:
a first pair of components comprising a capacitor and a resistor connected to each other in series, the first pair of components being connected to the third node;
a second pair of components comprising a capacitor and a resistor connected to each other in series, the second pair of components being connected to the fourth node, the first pair of components being positioned on the first side of the central axis and the second pair of components being positioned on the second side, opposite to the first side, of the central axis, and the first and the second pair of components being connected to each other via a second central connection node belonging to the central axis; and
a fifth inductor connected to the third node and a sixth inductor connected to the fourth node, the fifth inductor being further coupled to a fifth node and the sixth inductor being further coupled to a sixth node.

9. The circuit according to claim 8 wherein the second central connection node is connected to the rail of application of the first reference voltage.

10. The circuit according to claim 8 wherein the first central connection node is connected to a rail of application of a second reference voltage different from the first reference voltage, and the second central connection node is connected to the rail of application of the second reference voltage.

11. The circuit according to claim 8 wherein the second central connection node is floating.

12. The circuit according to claim 1, wherein the amplifier is a broadband amplifier configured to amplify an input signal over a frequency range having a bandwidth greater than or equal to 10 GHz.

13. The circuit according to claim 1, wherein the first pair of components and the second pair of components of each stage are arranged symmetrically with respect to the central axis.

14. An amplifier comprising:
a load impedance circuit comprising:
1.) a central axis;
2.) a first stage comprising:
a first pair of components comprising a capacitor and a resistor connected to each other in series, the first pair of components being connected to a first node;
a second pair of components comprising a capacitor and a resistor connected together in series, the second pair of components being connected to a second node, the first pair of components being positioned on a first side of the central axis and the second pari of components being positioned on a second side, opposite to the first side, of the central axis, and the first and second pair of components being connected to each other via a first central connection node belonging to the central axis; and
a first inductor connected to the first node and a second inductor connected to the second node, the first inductor being further coupled to a third node and the second inductor being further coupled to a fourth node; and
3.) a third inductor between the first node and a rail of application of a first reference voltage, and a fourth inductor between the second node and the rail of application of the first reference voltage.

15. The amplifier according to claim 14 configured to receive a radio wave, the radio wave having a frequency in a range from 1 GHz to 200 GHz.

16. The amplifier according to claim 14 wherein the first central connection node is connected to the rail of application of the first reference voltage.

17. The amplifier according to claim 14 wherein the first central connection node is connected to a rail of application of a second reference voltage different from the first reference voltage.

18. The amplifier according to claim 14, wherein the first central connection node is floating.

19. The amplifier according to claim 14, wherein the amplifier is a broadband amplifier configured to amplify an input signal over a frequency range having a bandwidth greater than or equal to 10 GHz.

20. The amplifier according to claim 14, wherein an inductive loop is configured to implement at least two inductors from among the first inductor, the second inductor, the third inductor, and the fourth inductor.
